(19) United States
(12) Patent Application Publication
(10) Pub. No.: US 2012/0126015 A1
(43) Pub. Date: May 24, 2012

(54) LIGHT SEAL GASKET FOR USING IN IMAGING-BASED BARCODE READER

(75) Inventors: Carl D. Wittenberg, Water Mill, NY (US); Mark E. Drzymala, Commack, NY (US); Chinh Tan, Setauket, NY (US); Wancheng Zhao, Selden, NY (US)

(73) Assignee: Motorola, Inc., Law Department, Schaumburg, IL (US)

(21) Appl. No.: 12/951,195

(22) Filed: Nov. 22, 2010

(51) Int. Cl. G06K 7/14; G06K 7/10; H05K 13/00

(52) U.S. Cl. 235/462.41; 29/592.1; 235/462.43

(57) ABSTRACT

The light seal gasket for using in a barcode reading arrangement includes (1) a skirt region configured to surround the solid-state imager on the circuit board and having a bottom surface for making a light seal with the circuit board, (2) a baffle tube configured for aligning with an opening on the chassis and having a top surface for making a light seal with the chassis, and (3) a diaphragm region configured to be bendable when the chassis and the circuit board are pressed towards each other with the light seal gasket sandwiched in-between.

### FIELD OF THE DISCLOSURE

The present disclosure relates generally to imaging-based barcode readers.

### BACKGROUND

Various electro-optical systems have been developed for reading optical indicia, such as barcodes. A barcode is a coded pattern of graphical indicia comprised of a series of bars and spaces of varying widths. In a barcode, the bars and spaces having differing light reflecting characteristics. Some of the barcodes have a one-dimensional structure in which bars and spaces are spaced apart in one direction to form a row of patterns. Examples of one-dimensional barcodes include Uniform Product Code (UPC), which is typically used in retail store sales. Some of the barcodes have a two-dimensional structure in which multiple rows of bar and space patterns are vertically stacked to form a single barcode. Examples of two-dimensional barcodes include Code 49 and PDF417.

Systems that use one or more solid-state imagers for reading and decoding barcodes are typically referred to as imaging-based barcode readers, imaging scanners, or imaging readers. A solid-state imager generally includes a plurality of photosensitive elements or pixels aligned in one or more arrays. Examples of solid-state imagers include charged coupled devices (CCD) or complementary metal oxide semiconductor (CMOS) imaging chips.

FIG. 1 shows an imaging scanner 50 in accordance with some embodiments. The imaging scanner 50 has a window 56 and a housing 58 with a handle. The imaging scanner 50 also has a base 52 for supporting itself on a countertop. The imaging scanner 50 can be used in a hands-free mode as a stationary workstation when it is placed on the countertop. The imaging scanner 50 can also be used in a handheld mode when it is picked up off the countertop and held in an operator's hand. In the hands-free mode, products can be slid, swiped past, or presented to the window 56. In the handheld mode, the imaging scanner 50 can be moved towards a barcode on a product, and a trigger 54 can be manually depressed to initiate imaging of the barcode. In some implementations, the base 52 can be omitted, and the housing 58 can also be in other shapes.

### SUMMARY

In one aspect, the invention is directed to a light seal gasket for using in a barcode reading arrangement. The barcode reading arrangement includes (1) a chassis and (2) a circuit board configured to hold a solid-state imager thereon, the solid-state imager having an array of photosensitive elements for capturing an image from a target object having a barcode The light seal gasket includes (1) a skirt region configured to surround the solid-state imager on the circuit board and having a bottom surface for making a light seal with the circuit board, (2) a baffle tube configured for aligning with an opening on the chassis and having a top surface for making a light seal with the chassis, and (3) a diaphragm region configured to be bendable when the chassis and the circuit board are pressed towards each other with the light seal gasket sandwiched in-between.

In another aspect, the invention is directed to a method for assembling a barcode reading arrangement. The barcode reading arrangement includes (1) a chassis and (2) a circuit board configured to hold a solid-state imager thereon. The solid-state imager has an array of photosensitive elements for capturing an image from a target object having a barcode. The method includes placing a light seal gasket between the circuit board and the chassis. The light seal gasket includes (1) a skirt region configured to surround the solid-state imager on the circuit board, (2) a baffle tube for aligning with an opening on the chassis, and (3) a diaphragm region between the skirt region and the baffle tube. The method also includes pressing the light seal gasket with forces between the circuit board and the chassis to make a light seal between the circuit board and a bottom surface of the skirt region and to make a light seal between the chassis and a top surface of the baffle tube.

The advantages of the present invention will become apparent to those skilled in the art upon a reading of the following specification of the invention and a study of the several figures of the drawings.

### BRIEF DESCRIPTION OF THE FIGURES

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 shows an imaging scanner in accordance with some embodiments.

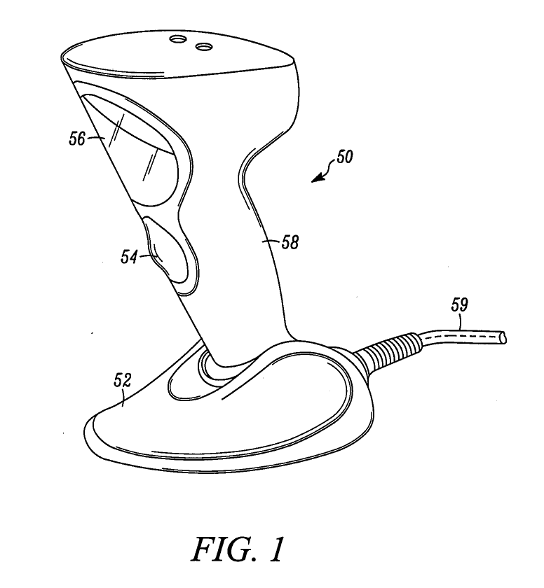

FIG. 2 is a schematic of an imaging scanner in accordance with some embodiments.

FIG. 3 depicts an imaging scanner in accordance with some existing implementations.

FIG. 4 shows an improved scan engine for the imaging scanner in accordance with some embodiments.

FIG. 5 shows a schematic of the light seal gasket in accordance with some embodiments.

FIG. 6 is the isometric view of the light seal gasket in accordance with some embodiments.

FIG. 7 shows that ridges can be added to the interior surface of the baffle tubes to reflect grazing light directly away from the imaging sensors in accordance with some embodiments.

FIG. 8 shows a scan engine that include one imaging systems with one corresponding solid-state imager in accordance with some embodiments.

FIG. 9 shows the light seal gasket for using in the scan engine of FIG. 8 in accordance with some embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

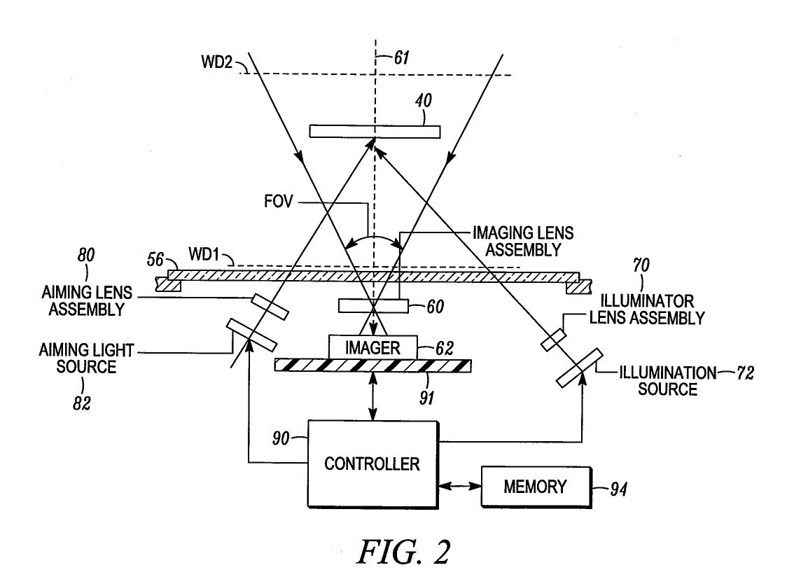

FIG. 2 is a schematic of an imaging scanner 50 in accordance with some embodiments. The imaging scanner 50 in FIG. 2 includes the following components: (1) a solid-state imager 62 positioned behind an imaging lens assembly 60; (2) an illuminating lens assembly 70 positioned in front of an illumination source 72; (3) an aiming lens assembly 80 positioned in front of an aiming light source 82; and (4) a controller 90. In FIG. 2, the imaging lens assembly 60, the illuminating lens assembly 70, and the aiming lens assembly 80 are positioned behind the window 56. The solid-state imager 62 is mounted on a printed circuit board 91 in the imaging scanner.

The solid-state imager 62 can be a CCD or a CMOS imaging device. The solid-state imager 62 generally includes multiple pixel elements. These multiple pixel elements can be formed by a one-dimensional array of photosensitive elements arranged linearly in a single row. These multiple pixel elements can also be formed by a two-dimensional array of photosensitive elements arranged in mutually orthogonal rows and columns. The solid-state imager 62 is operative to detect light captured by an imaging lens assembly 60 along an optical path or axis 61 through the window 56. Generally, the solid-state imager 62 and the imaging lens assembly 60 are designed to operate together for capturing light scattered or reflected from a barcode 40 as pixel data over a two-dimensional field of view (FOV).

The barcode 40 generally can be located anywhere in a working range of distances between a close-in working distance (WD1) and a far-out working distance (WD2). In one specific implementation, WD1 is about a few inches from the window 56, and WD2 is about a few feet from the window 56. Some of the imaging scanners can include a range finding system for measuring the distance between the barcode 40 and the imaging lens assembly 60. Some of the imaging scanners can include an auto-focus system to enable a barcode be more clearly imaged with the solid-state imager 62 based on the measured distance of this barcode. In some implementations of the auto-focus system, the focus length of the imaging lens assembly 60 is adjusted based on the measured distance of the barcode. In some other implementations of the auto-focus system, the distance between the imaging lens assembly 60 and the solid-state imager 62 is adjusted based on the measured distance of the barcode.

In FIG. 2, the illuminating lens assembly 70 and the illumination source 72 are designed to operate together for generating an illuminating light towards the barcode 40 during an illumination time period. The illumination source 72 can include one or more light emitting diodes (LED). The illumination source 72 can also include a laser or other kind of light sources. The aiming lens assembly 80 and the aiming light source 82 are designed to operate together for generating a visible aiming light pattern towards the barcode 40. Such aiming pattern can be used by the operator to accurately aim the imaging scanner at the barcode. The aiming light source 82 can include one or more light emitting diodes (LED). The aiming light source 82 can also include a laser or other kind of light sources.

In FIG. 2, the controller 90, such as a microprocessor, is operatively connected to the solid-state imager 62, the illumination source 72, and the aiming light source 82 for controlling the operation of these components. The controller 90 can also be used to control other devices in the imaging scanner. The imaging scanner 50 includes a memory 94 that can be accessible by the controller 90 for storing and retrieving data. In many embodiments, the controller 90 also includes a decoder for decoding one or more barcodes that are within the field of view (FOV) of the imaging scanner 50. In some implementations, the barcode 40 can be decoded by digitally processing a captured image of the barcode with a microprocessor.

In operation, in accordance with some embodiments, the controller 90 sends a command signal to energize the illumination source 72 for a predetermined illumination time period. The controller 90 then exposes the solid-state imager 62 to capture an image of the barcode 40. The captured image of the barcode 40 is transferred to the controller 90 as pixel data. Such pixel data is digitally processed by the decoder in the controller 90 to decode the barcode. The information obtained from decoding the barcode 40 is then stored in the memory 94 or sent to other devices for further processing.

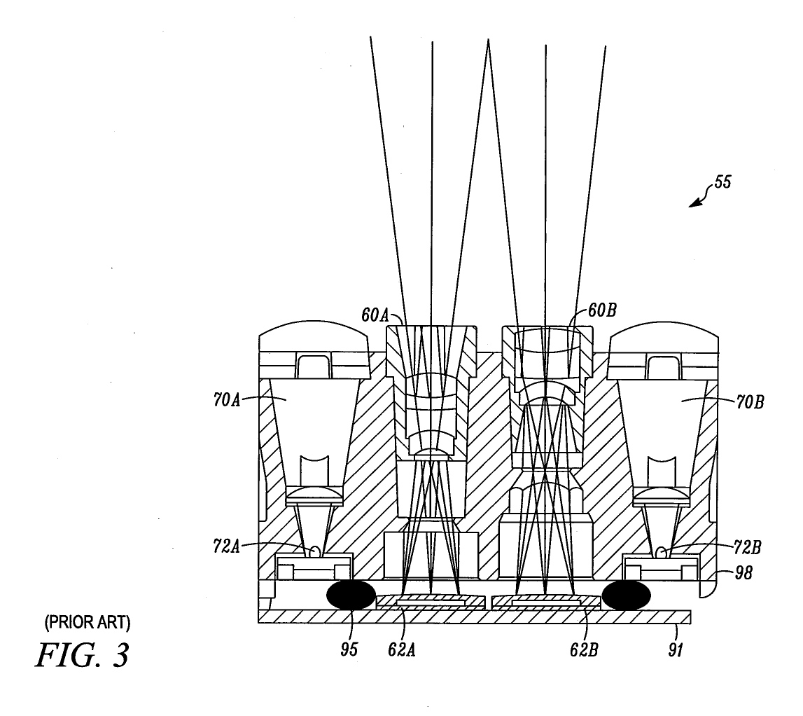

FIG. 3 shows an implementation of a scan engine 55 for use in the imaging scanner 50. The scan engine 55 in FIG. 3 includes (1) a first imaging system that includes a solid-state imager 62A positioned behind an imaging lens assembly 60A and (2) a second imaging system that includes a solid-state imager 62B positioned behind an imaging lens assembly 60B. Both the solid-state imager 62A and the solid-state imager 62B are mounted on a circuit board 91. These two imaging systems are designed to provide an extended range of working distances. One of the imaging systems can be used for capturing the image of a barcode when the barcode is located near the imaging scanner 50, and the other one of the imaging systems can be used for capturing the image of a barcode when the barcode is located far away from the imaging scanner 50. The scan engine 55 in FIG. 3 also includes (1) a first illumination source 72B positioned behind a first illuminating lens assembly 70A and (2) a second illumination source 72B positioned behind a second illuminating lens assembly 70B. The illuminating lens assemblies (i.e., 70A and 70B) and the imaging lens assemblies (i.e., 70A and 70B) are all inserted into some opening spaces of a chassis 98.

The scan engine 55 for reading barcodes usually is in the form of a miniature imaging device that requires a strategy for isolating its imaging sensors from ambient light. For a very small device, the structures used in a traditional camera are impractical. An opaque adhesive between the sensor PCB and the rest of the optical system can be used to block ambient light, but leads to a final assembly that cannot be disassembled for rework. An elastomeric gasket (e.g., an o-ring 95 as shown in FIG. 3) can be used to seal light from the sensors, placed between the sensor PCB and the remainder of the optical assembly. However, compressing a seal gasket will result in microscopic deformations to the sensor PCB. These deformations will change over time as the gasket relaxes, leading to loss of focus as the sensor PCB moves slightly.

In one example as shown in FIG. 3, the o-ring 95 has to be thick enough to account for all of the mechanical tolerances between the sensor PCB 91, the chassis 98, and the o-ring itself 95, to ensure that the o-ring is compressed. These tolerances, including the error in flatness of the PCB, can add up to ±0.3 mm error in the PCB-to-o-ring distance. However, due to space constraints, the o-ring itself may be no more than 2 mm thick. The o-ring has to be thick enough to fill the gap when the error in the distance is +0.3 mm, leading to 0.6 mm compression of the o-ring in the situation when the gap is 0.3 mm. For 0.6 mm compression, the strain on the 2 mm o-ring will be 0.6 mm/2 mm=0.3=30%. Many elastomeric materials can handle this sort of compression in plumbing and automotive-type applications without problems. However, for a small, sensitive optical assembly, this high compressive strain on the seal leads to high forces on the sensor PCB 91 distorting it. The distortion can lead to loss of board flatness, which will cause non-uniform image quality. In many situations the position of the sensor (e.g., the solid-state imager 62A) must be stable within 0.005 mm or less relative to the lenses in the system (e.g., the imaging lens assemblies 60A and 60B) to maintain focus. As the o-ring material relaxes, the force it places on the sensor PCB 91 will diminish and the sensor PCB 91 will bend back towards the chassis 98, leading to loss of focus.

An additional problem is that optical bores in a cast metal chassis necessarily have smooth walls, because the diecasting cores that form the bores must be smooth to pull out of the chassis during casting. These smooth walls can then reflect stray light from outside of the intended field of view of the optical system, sending the stray light rays onto the active area of the imaging sensors. These stray light reflections cause unwanted artifacts on the final images formed by the imaging device. Therefore, better light sealing technology for isolating the imaging sensors is needed.

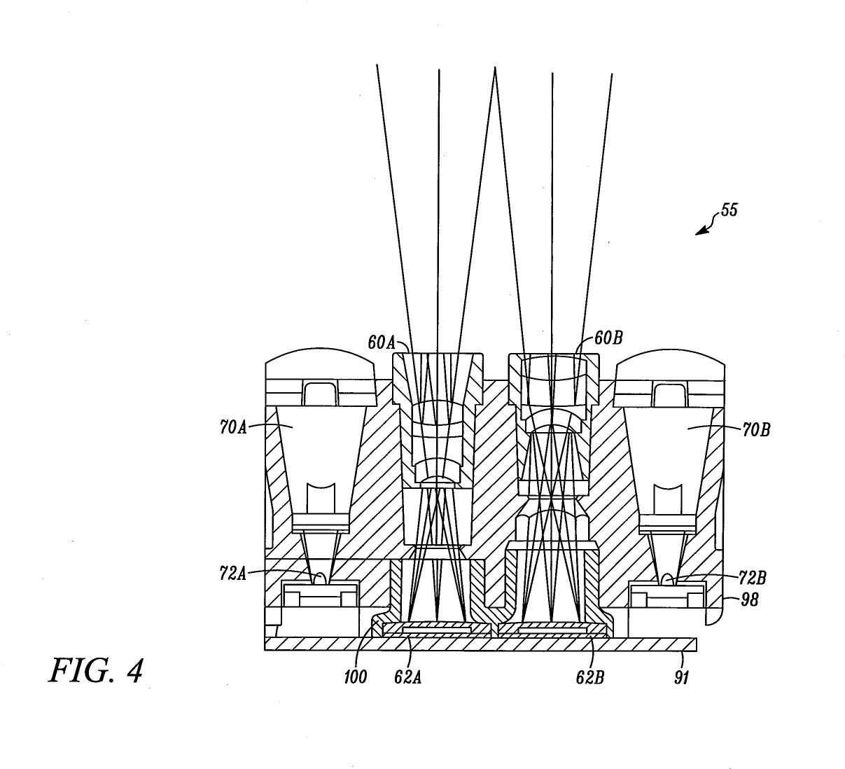

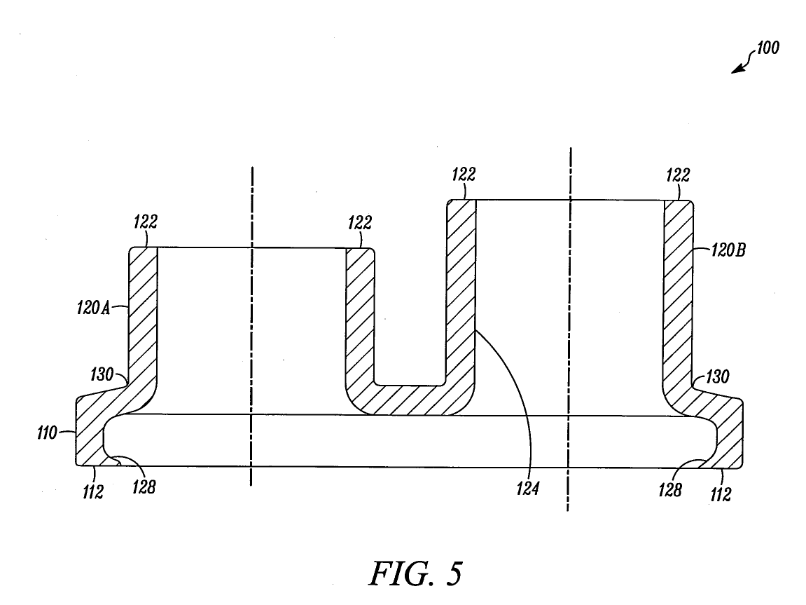

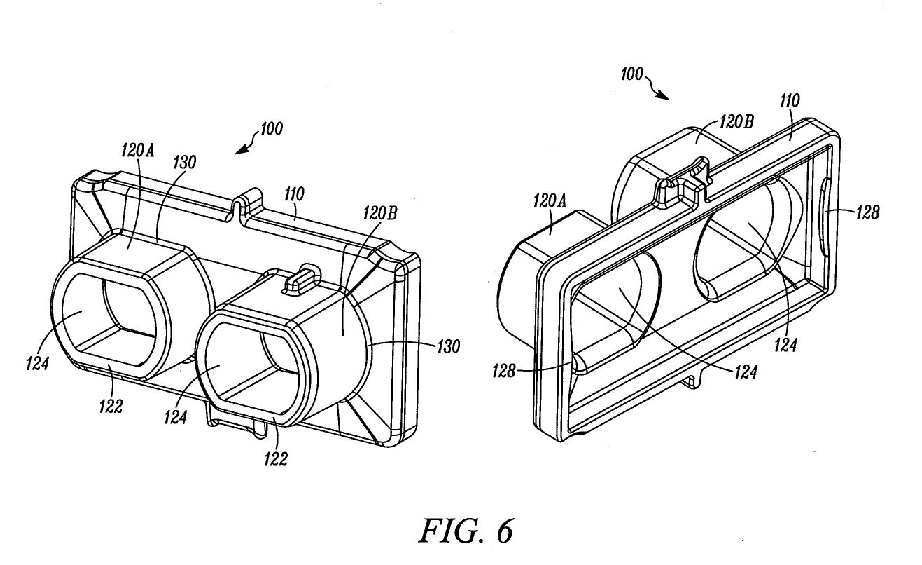

FIG. 4 shows an improved scan engine 55 for the imaging scanner 50 in accordance with some embodiments. In FIG. 4, a light seal gasket 100 is used for isolating the solid-state imagers 62A and 62B from ambient light. FIG. 5 shows a schematic of the light seal gasket 100 in accordance with some embodiments. FIG. 6 is the isometric view of the light seal gasket 100 in accordance with some embodiments. As shown in FIG. 5 and FIG. 6, the light seal gasket 100 includes a skirt region 110, a baffle tube 120A, a baffle tube 120B, and a diaphragm region 130. As shown in FIGS. 4-6, the skirt region 110 is configured to surround the solid-state imagers 62A and 62B on the circuit board 91. In one implementation, the skirt region 110 is a rectangular skirt region. The skirt region 110 can also be in other shape. As shown in FIGS. 4-6, the skirt region 110 has a bottom surface 112 for making a light seal with the circuit board 91. Similarly, each of the baffle tubes 120A and 120B has a top surface 122 for making a light seal with the chassis 98. The baffle tubes 120A and 120B are configured to align respectively with the imaging lens assemblies 60A and 60B. The diaphragm region 130 is configured to be bendable when the chassis 98 is pressed against the circuit board 91 through the light seal gasket 100. In one implementation, the light seal gasket 100 is molded from elastomer material.

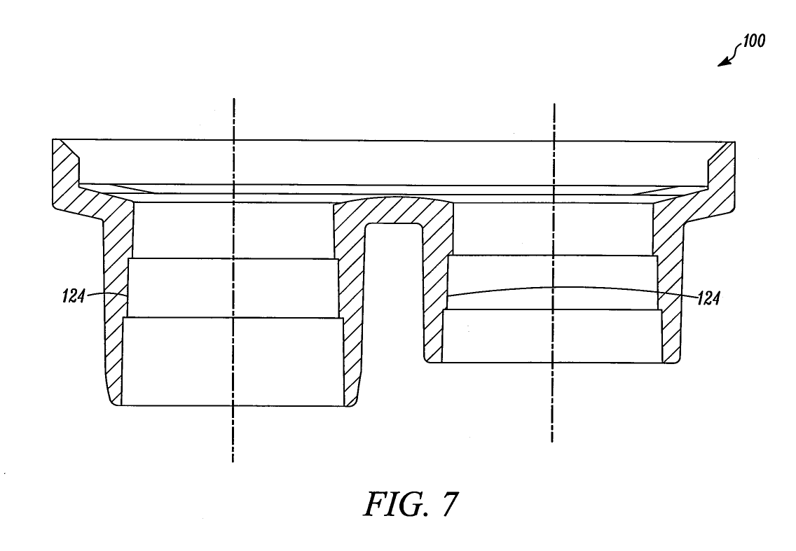

The interior surface 124 of the baffle tubes 120A and 120B are configured to be as non-reflective as possible. In some implementations, the interior surface 124 can be configured to be optically diffusive. The light seal gasket 100 can be made black in color. In one implementation, the interior surface 124 is made to have a specular reflectance less than 0.2%. In one implementation as shown in FIG. 5, the interior surface 124 of the baffle tubes 120A and 120B are provided with sandblasted finish. In some implementations, the nonreflective properties of the interior surface 124 of the baffle tubes 120A and 120B can be enhanced with mechanical textures. In one example as shown in FIG. 7, ridges can be added to the interior surface 124 of the baffle tubes 120A and 120B to reflect grazing light directly away from the imaging sensors.

In some implementations, as shown in FIG. 5 and FIG. 6, the light seal gasket 100 can also includes a pair of undercut hooks 128 at a bottom of the skirt region 110. The undercut hooks 128 can be designed to cling the light seal gasket 100 onto the solid-state imagers 62A and 62B on the circuit board 91. This is enabled by the fact that the sensor chips are BGA (ball grid array) packages, which stand roughly 0.4 mm off the circuit board on solder balls. This relatively large gap allows the gasket to grip gently on the underside of the sensor chips, allowing the gasket to cling when the sensor PCB is held with the sensors face-down. This enables the drop-in field stops (if there is any) to be first placed into the chassis, and then for the sensor PCB with the gasket pre-loaded onto it to be placed onto the chassis without disturbing the field stop. After the sensor PCB and gasket are in position, screws can be applied through the sensor PCB to hold into permanently onto the chassis.

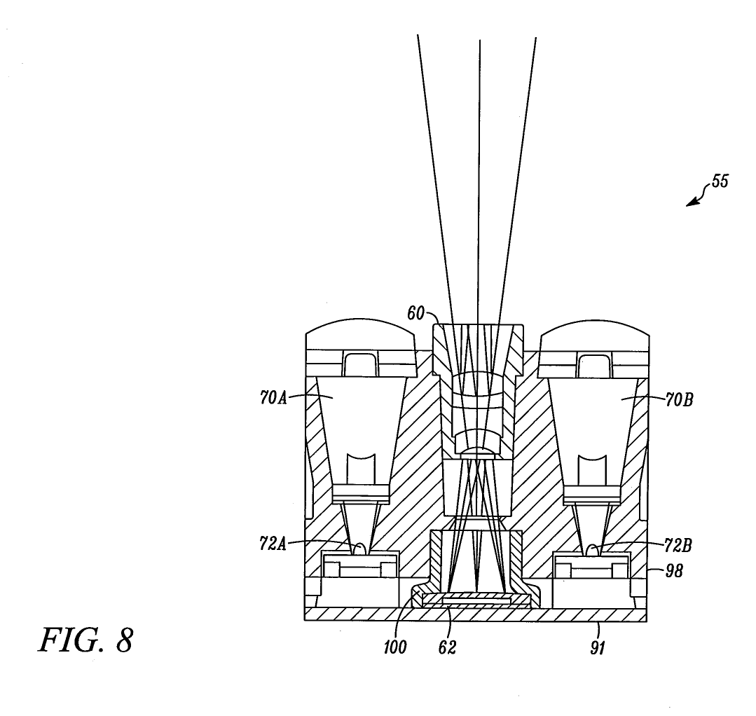

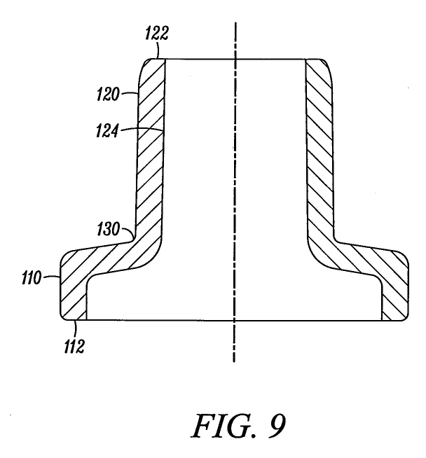

In FIG. 4, the scan engine 55 includes two imaging systems with two corresponding solid-state imagers 62A and 62B, and the light seal gasket 100 includes two corresponding baffle tubes 120A and 120B. In some other implementations, as shown in FIG. 8, the scan engine 55 includes one imaging system with one corresponding solid-state imager 62, and the light seal gasket 100 includes one corresponding baffle tube 120. FIG. 9 shows the light seal gasket for using in the scan engine 55 of FIG. 8 in accordance with some embodiments. In FIG. 8, the light seal gasket 100 includes: (1) a skirt region 110 configured to surround the solid-state imager on the circuit board and having a bottom surface 112 for making a light seal with the circuit board; (2) a baffle tube 120 configured for aligning with an opening on the chassis and having a top surface 122 for making a light seal with the chassis; and (3) a diaphragm region 130 configured to be bendable when the chassis and the circuit board are pressed towards each other with the light seal gasket sandwiched in-between. The baffle tube 120 includes an interior surface 124 that is essentially non-reflective optically.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed is:

1. An apparatus comprising:
a circuit board configured to hold a solid-state imager thereon, the solid-state imager having an array of photosensitive elements for capturing an image from a target object having a barcode;
a chassis having an opening;
a lens system operative to focus light reflected from the target object onto the array of photosensitive elements in the solid-state imager through the opening of the chassis; and
a light seal gasket includes,
(1) a skirt region configured to surround the solid-state imager on the circuit board and having a bottom surface for making a light seal with the circuit board,
(2) a baffle tube configured to align with the lens system and having a top surface for making a light seal with the chassis, and
(3) a diaphragm region configured to be bendable when the chassis is pressed against the circuit board through the light seal gasket.

2. The apparatus of claim 1, wherein the skirt region is a rectangular skirt region.

3. The apparatus of claim 1, wherein the light seal gasket is molded from elastomer material.

4. The apparatus of claim 1, wherein the light seal gasket is black in color.

5. The apparatus of claim 1, wherein the baffle tube includes an interior surface that is configured to have a specular reflectance less than 0.2%.

6. The apparatus of claim 1, wherein the baffle tube includes an interior surface that is configured to be optically non-reflective.

7. The apparatus of claim 1, wherein the baffle tube includes an interior surface that is configured to be optically diffusive.

8. The apparatus of claim 1, wherein the baffle tube includes an interior surface with sandblasted finish.

9. The apparatus of claim 1, wherein the baffle tube includes in an interior surface having mechanical textures thereon for reflecting grazing light directly away from the solid-state imager.

10. The apparatus of claim 1, wherein the baffle tube includes in an interior surface having ridges thereon for reflecting grazing light directly away from the solid-state imager.

11. The apparatus of claim 1, wherein the light seal gasket further comprises:
a pair of undercut hooks at a bottom of the skirt region and configured for clinging the light seal gasket onto the solid-state imager on the circuit board.

12. A method for assembling a barcode reading arrangement, the barcode reading arrangement including (1) a chassis and (2) a circuit board configured to hold a solid-state imager thereon, the solid-state imager having an array of photosensitive elements for capturing an image from a target object having a barcode, the method comprises:
placing a light seal gasket between the circuit board and the chassis, the light seal gasket including (1) a skirt region configured to surround the solid-state imager on the circuit board, (2) a baffle tube for aligning with an opening on the chassis, and (3) a diaphragm region between the skirt region and the baffle tube; and
pressing the light seal gasket with forces between the circuit board and the chassis to make a light seal between the circuit board and a bottom surface of the skirt region and to make a light seal between the chassis and a top surface of the baffle tube.

13. The method of claim 12, wherein the step of pressing the light seal gasket with forces between the circuit board and the chassis includes causing mechanical bending in the diaphragm region.

14. The method of claim 12, wherein the step of placing the light seal gasket between the circuit board and the chassis comprises:
attaching the light seal gasket on the circuit board by clinging the light seal gasket onto the solid-state imager with a pair of undercut hooks at a bottom of the skirt region to form a subassembly; and
assembling the chassis with the subassembly having the light seal gasket on the circuit board.

15. The method of claim 12, further comprising:
molding the light seal gasket from elastomer material.

16. The method of claim 12, further comprising:
sandblasting an interior surface of the baffle tube to provide an optically non-reflective finish.

17. A light seal gasket for using in a barcode reading arrangement, the barcode reading arrangement including (1) a chassis and (2) a circuit board configured to hold a solid-state imager thereon, the solid-state imager having an array of photosensitive elements for capturing an image from a target object having a barcode, the light seal gasket comprising:
a skirt region configured to surround the solid-state imager on the circuit board and having a bottom surface for making a light seal with the circuit board,
a baffle tube configured for aligning with an opening on the chassis and having a top surface for making a light seal with the chassis, and
a diaphragm region configured to be bendable when the chassis and the circuit board are pressed towards each other with the light seal gasket sandwiched in-between.

18. The light seal gasket of claim 17, wherein the light seal gasket is molded from elastomer material.

19. The light seal gasket of claim 17, wherein the baffle tube includes an interior surface that is configured to be optically non-reflective.

20. The light seal gasket of claim 17, wherein the baffle tube includes an interior surface that is configured to be optically diffusive.

21. The light seal gasket of claim 17, wherein the baffle tube includes an interior surface with sandblasted finish.

22. The light seal gasket of claim 17, wherein the baffle tube includes in an interior surface having mechanical textures thereon for reflecting grazing light directly away from the solid-state imager.

23. The light seal gasket of claim 17, wherein the baffle tube includes in an interior surface having ridges thereon for reflecting grazing light directly away from the solid-state imager.
